(19) United States
(12) Patent Application Publication
(10) Pub. No.: US 2006/0077747 A1
(43) Pub. Date: Apr. 13, 2006

(54) Semiconductor device and data reading method

(76) Inventors: Masaru Yano, Tokyo (JP); Kazuhide Kurosaki, Tokyo (JP); Kazuhiro Kitazaki, Tokyo (JP)

Correspondence Address: Paul J. Winters, 307 Cypress Point Drive, Mountain View, CA, 94043, US

(21) Appl. No.: 11/228,840

(22) Filed: Sep. 16, 2005

Related U.S. Application Data
(63) Continuation of application No. PCT/JP04/14253, filed on Sep. 29, 2004.

(51) Int. Cl. G11C 8/00

(52) U.S. Cl. 365/230.06

(57) ABSTRACT

The present invention has an arrangement that includes a Y decoder that selects a main bit line MBL to which sub bit lines SBL connected to memory cells MC are connected and selects main bit lines MBL adjacent to the selected main bit line MBL, and a YRST transistor that connects the adjacent main bit lines MBL to a given interconnection line and set these main bit lines to a given voltage. With this structure, it is possible to restrain noise from the adjacent main bit lines MBL to the minimum and prevent degradation of the voltage margin.

### CROSS REFERENCE TO RELATED APPLICATIONS

This is a continuation of International Application No. PCT/JP2004/014253, filed Sep. 29, 2004.

### BACKGROUND OF THE INVENTION

1. Field of the Invention

The present invention relates to a semiconductor device, and more particularly, a method of reading data from a semiconductor device equipped with a NOR-type array structure.

2. Description of the Related Art

Generally, a semiconductor device equipped with the NOR-type array structure has an arrangement in which bit lines adjacent to a selected bit line are both set in the floating state. However, there is a possibility that the voltage margin may be degraded due to the influence of a coupling noise with the unselected neighboring bit lines and the recent trend of voltage-lowering and miniaturization of the semiconductor devices if the unselected bit lines are in the floating state, and the semiconductor device may malfunction. Particularly, the degradation of the voltage margin is serious to a multi-bit memory cell.

There is a proposal of the data reading method directed to coping with the above-mentioned problem, in which the unselected bit lines adjacent to the selected bit line are maintained at a given voltage to enhance the shield effect and prevent the occurrence of malfunction.

Japanese Patent Application Publication No. 7-45087 shows an arrangement in which the data lines (bit lines) are grouped into even-numbered data lines and odd-numbered data lines, and a MOSFET is provided to supplies the ground potential to the data lines in the inactive state. Japanese Patent Application Publication No. 2002-100196 discloses a bit line grounding circuit composed of multiple transistors, each of which connects the respective one of the bit lines to the ground potential.

However, these publications disclose the use of sub bit line, which are directly connected to the memory cells and selected for shielding. It is therefore necessary to provide transistors for selecting the sub bit lines. This increases the number of components and the circuit scale.

### SUMMARY OF THE INVENTION

The present invention has been made taking the above into consideration and has an object of providing a semiconductor device capable of reading data stably without increasing the circuit scale.

This object of the present invention is achieved by a semiconductor device including: a main bit line decoder for selecting one of main bit lines to which sub bit lines connected to memory cells are selectively connected; and a first switch setting an adjacent main bit line adjacent to a selected one of the main bit lines at a given voltage under the control of the main bit line decoder.

By setting the main bit lines adjacent to the selected main bit line to the given voltage, it is possible to restrain noise from the adjoining the main and sub bit lines to the minimum and prevent degradation of the voltage margin. This makes it possible to prevent the occurrence of malfunction at the time of data reading. The main bit lines are set to the given voltage each time one of the main bit lines is selected. This arrangement contributes to preventing an increase of the number of components and a resultant increase of the circuit scale.

The first switch may connect the adjacent main bit lines to an interconnection line that is set at the given voltage.

By connecting the adjacent main bit line or lines to the interconnection line set at the given voltage, it is possible to stabilize the voltages of the main bit lines and to thus restrain noise from the adjoining the main and sub bit lines to the minimum and prevent degradation of the voltage margin.

In the above semiconductor device, the first switch may connect the adjacent main bit line to ground.

By connecting the adjacent main bit line or lines to ground by the first switch, the voltages of the main bit lines can be stabilized. It is thus possible to restrain noise from the adjoining the main and sub bit lines to the minimum and prevent degradation of the voltage margin.

The semiconductor device may further include: a sub bit line decoder for selecting at least one of sub bit lines connected to said selected one of the main bit lines; and a second switch connecting an adjacent sub bit line adjacent to said at least one of the sub bit lines to the adjacent main bit line under the control of the sub bit line decoder, so that the adjacent sub bit line can be set at the given voltage.

By setting the adjacent sub bit line or lines at the given voltage even in the sub bit lines, it is possible to restrain the influence of noise to the selected bit line and prevent degradation of the voltage margin. Thus, the occurrence of malfunction can be prevented at the time of, for example, reading data.

In the above semiconductor device, at the time of reading, the main bit line decoder may control the first switch so that the adjacent main bit line can be set at the given voltage. At the time of reading data, an increased influence of noise from the bit line or lines adjacent to the selected bit line takes place. By setting the adjacent main bit lines to the given voltage, it is possible to avoid the influence of nose.

In the above semiconductor device, the first switch may include transistors each of which is provided on a corresponding one of the main bit lines; and one of the transistors associated with the adjacent main bit line is turned on so that the adjacent main bit line can be set at the given voltage.

Thus, there is no need to provide a logic circuit or the like that sets the adjacent main bit line or lines to the given voltage.

In the above semiconductor device, the second switch may include a transistor for connecting the adjacent sub bit line to the adjacent main bit line.

The use of the transistor for the second switch simplifies the circuit configuration.

In the above semiconductor device, the semiconductor device may be configured so that it has a NOR array in which: the memory cells have charge hold layers and are arranged in an array having rows and columns; word lines connect control gates of the memory cells in a direction of the rows; and data is read from and written into the memory cells via the sub bit lines.

With this structure, it is possible to accurately read data from the semiconductor device with the array structure that is a great noise source.

In the semiconductor device, the array may have an arrangement in which adjacent ones of the sub bit lines are connected to different main bit lines.

With this structure, it is possible to accurately read data from the semiconductor device with the array structure that is a great noise source.

The present invention includes a method of reading data comprising the steps of: selecting one of main bit lines to which sub bit lines connected to memory cells are selectively connected; and setting an adjacent main bit line adjacent to a selected one of the main bit lines at a given voltage.

By setting the main bit lines adjacent to the selected main bit line to the given voltage, it is possible to restrain noise from the adjoining the main and sub bit lines to the minimum and prevent degradation of the voltage margin. This makes it possible to prevent the occurrence of malfunction at the time of data reading. The main bit lines are set to the given voltage each time one of the main bit lines is selected. This arrangement contributes to preventing an increase of the number of components and a resultant increase of the circuit scale.

### BRIEF DESCRIPTION OF THE DRAWINGS

Other objects, features and advantages of the present invention will become more apparent from the following detailed description when read in conjunction with the accompanying drawings, in which:

FIG. 1 is a block diagram of a structure of a semiconductor device;

FIG. 2 is a diagram of an array structure of a cell array part;

FIG. 3 shows a wiring layout of sub bit lines and structures of U-sector transistors, and L-sector transistors;

FIG. 4 is a diagram of a structure of a Y gate;

FIG. 5 is a diagram of a connection route of a selected main bit line and sub bit lines adjacent thereto;

FIG. 6 is a diagram of a connection route of a selected sub bit line and another sub bit line adjacent thereto; and

FIG. 7 is a waveform diagram of signals that are output from a Y decoder and an S decoder.

### DESCRIPTION OF THE PREFERRED EMBODIMENTS

A description will now be given of preferred embodiments of the present invention with reference to the accompanying drawings.

### First Embodiment

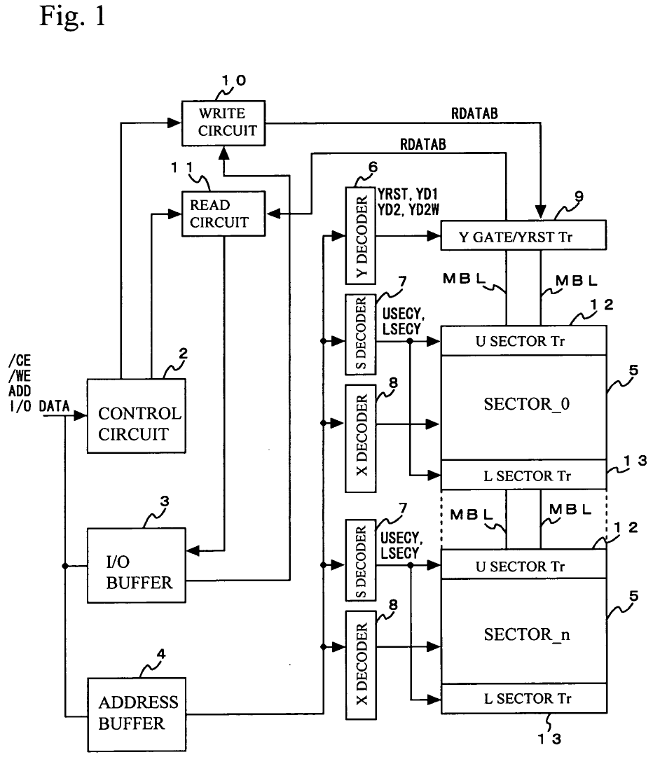

The structure of an embodiment of the present invention will now be described with reference to FIG. 1. A semiconductor device 1 of the present embodiment is equipped with a control circuit 2, an input/output buffer 3, and an address buffer 4, a cell array part 5, a Y decoder (main bit line select decoder) 6, an S decoder (sub bit line select decoder) 7, an X decoder 8, a Y gate 9, a write circuit 10 and a read circuit 11. The semiconductor device may be a semiconductor device packaged solely such as a flash memory, or may be incorporated as a part of a semiconductor device such as a system LSI.

The control circuit 2 has a built-in command register, and operates in synchronism with a chip enable signal CE and a write enable signal WE supplied from the outside of the semiconductor device. The control circuit 2 produces timing signals based on a command externally supplied, and sends these timing signals to related parts of the semiconductor device.

The input/output buffer 4 latches address information externally supplied, and supplies the latched address information to the Y decoder 6, the X decoder 8 and the S decoder 7.

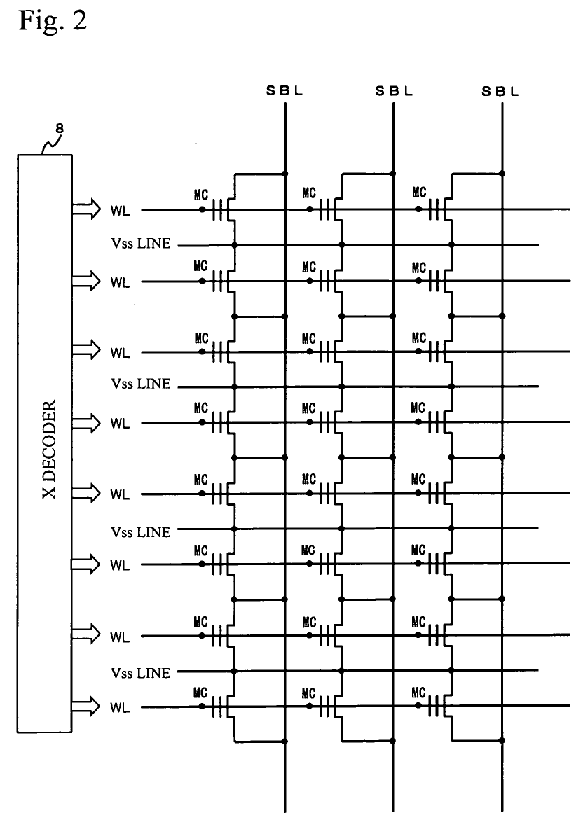

FIG. 2 shows a structure of the cell array part 5, which is equipped with memory cells MC, each of which has a control gate connected to a word line WL, a drain connected to a sub bit line SBL and a source connected to an array Vss line. The memory cells MC has a charge storing structure composed of a gate insulation film made up of a first gate oxide film, a charge trap layer formed by an insulation film and a second gate oxide film, and a gate electrode, which are laminated in turn. The charge trap layer may be a nitride film in which a charge is trapped so that the threshold value for discriminating data “0” and “1” from each other can be changed. The charge trap layer, which may be the nitride film, is an insulation film, and the charge trapped therein does not move. The memory cells MC may have another type of charge storing structure, such as a memory cell with a floating gate made of polysilicon. The cell array part 5 has the NOR-type array structure in which the memory cells MC thus configured are arranged in rows and columns.

At the time of reading data, data in the memory cell MC specified through the activated word line is read out to the associated sub bit line SBL. At the time of writing (programming) or erasing, the word lines and bit lines (sub bit lines and main bit lines) are set to appropriate voltages for programming or erasing in order to inject charges into the memory cells or remove charges therefrom.

The X decoder 8 selectively drives the word lines WL specified by the addresses respectively supplied at the time of programming, erasing and reading. The selected word line or word lines WL are supplied with a high voltage. The Y decoder 6 specifies the address in the Y direction indicated by the address signal, and turns ON the associated transistor in the Y gate 9. Signals YD1, YD2 and YD2W and a signal YRST are supplied from the Y decoder 6. The signals YD1, YD2 and YD2W turn ON and OFF the transistors in the Y gate 9, and the signal YRST turns ON and OFF a Y reset transistor (first switch)(hereinafter sometimes referred to as YRESTTr) in the Y gate 9.

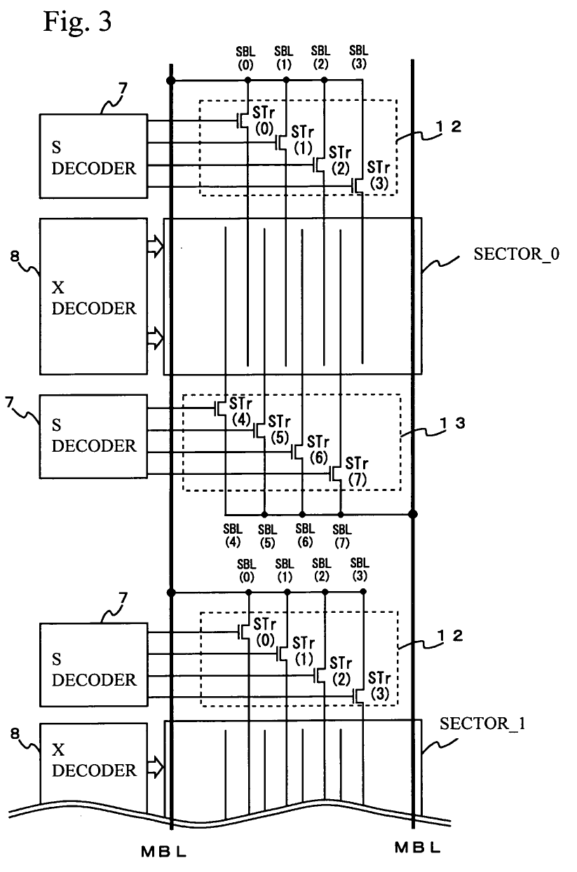

The S decoder 7 produces signals USECY and LSECY for selecting the sub bit lines SBL, and supplies these signals to a U-sector transistor group (hereinafter sometimes referred to as U-sector Tr) 12 and an L-sector transistor group (hereinafter sometimes referred to as L-sector Tr) 13. As shown in FIG. 3, each of the U-sector Tr groups 12 and the L-sector transistor groups 13 has sub bit lines SBL directly connected to the memory cells MC, and select transistors STr (second switches) for making a selective connection with the associated main bit line MBL. The select transistors STr are turned ON and OFF by the signals USECY and LSECY from the S decoder 7, so that the main bit lines MBL and the sub bit lines SBL are selectively connected.

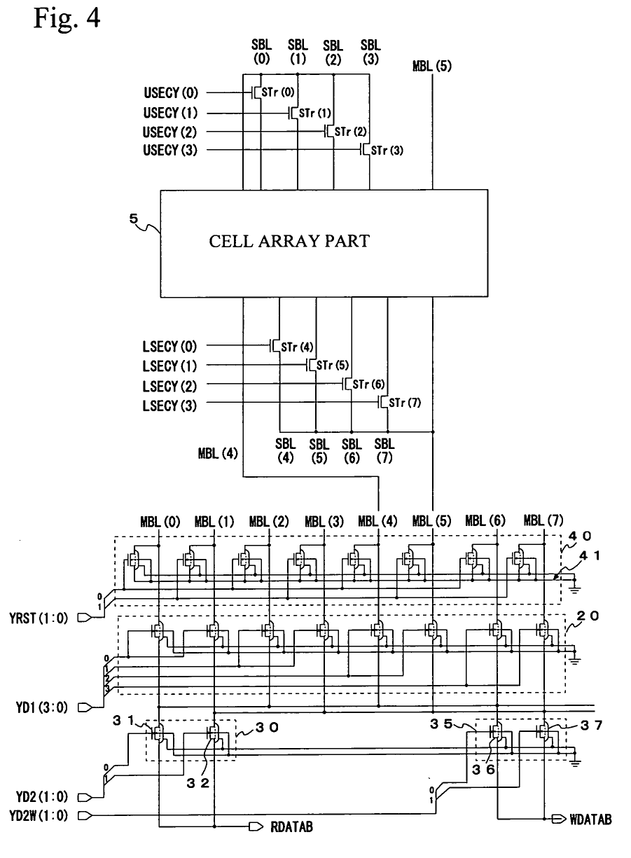

Further, as shown in FIG. 3, four sub bit lines SBL are connected to one main bit line MBL, and are adjacent to sub bit lines SBL connected to another main bit line MBL adjacent to said one main bit line MBL. One of the two neighboring main bit lines MBL is connected to the sub bit lines SBL at the upper side of the sector, the other main bit line MBL is connected to the sub bit lines SBL at the lower side thereof. Although only two main bit lines MBL are shown in FIG. 3, in practice, a plurality of main bit lines (MBL(0)-MBL(7)) are provided in the cell array part 4, as shown in FIG. 4.

The Y gate 9 selectively connects the main bit lines MBL of the cell array part 5 to the read circuit 11 on the basis of the decoded address signal at the time of reading. This establishes a path for writing data into the specified memory cell MC and reading data therefrom.

The write circuit 10 latches data from the input/output buffer 3. The data latched in the write circuit 10 is output to the main bit line MBL selected by the Y gate 9 and the sub bit lines connected thereto.

The read circuit 11 includes a sense amplifier, which amplifies data read to the bit line (more specifically, the sub bit line SBL and the main bit line MBL) at the time of reading to a sufficient level that enables the read data to be handled as digital signal. The read circuit 11 makes a decision on the data read from the cell array 5. The current corresponding to data supplied from the cell array 5 in connection with the specified address defined by the X decoder 8 and the Y decoder 6 is compared with a reference current in order to determine whether the read data is 0 or 1. The reference current is supplied from a not-shown reference cell. The determination result is supplied, as read data, to the input/output buffer 3.

A description will now be given of the Y gate and YRST transistors with reference to FIG. 4. The Y gate 9 includes a first group 20 of transistors respectively provided for the main bit lines MBL, a group 30 of read select transistors for making connections between the main bit lines MBL and the read circuit 11, a group 35 of write select transistors for connecting the main bit lines MBL and the write circuit 10, and a group 40 of YRST transistors. The group 30 of read select transistors, and the group 35 of the write select transistors are referred to as a second transistor group as a whole.

Each transistor of the first group 20 is supplied, via the gate, with a signal YD1 produced by decoding by the Y decoder 6. The signal YD1 is composed of four signals YD1(0), YD1(1), YD1(2), YD1(3). The signal YD1(0) is supplied to the transistors on the main bit lines MBL(0) and MBL(1). The signal YD1(1) is supplied to the transistors on the main bit lines MBL(2) and MBL(3). The signal YD1(2) is supplied to the transistors on the main bit lines MBL(4) and MBL(5). The signal YD1(3) is supplied to the transistors on the main bit lines MBL(6) and MBL(7). Thus, the main bit lines MBL(0) and MBL(1) are selected by the signal YD1(0), and MBL(2) and MBL(3) are selected by the signal YD1(1). The main bit lines MBL(4) and MBL(5) are selected by the signal YD 1(2), and MBL(6) and MBL(7) are selected by the signal YD1(3).

The read select transistor group 30 is composed of an even-numbered select transistor 31 arranged on the even-numbered main bit lines MBL(0), (2), (4) and (6), and an odd-numbered select transistor 32 arranged on the odd-numbered main bit lines MBL(1), (3), (5) and (7).

The read select transistor the group 30 is supplied, via the gates of the transistors, with the signal YD2 obtained by decoding by the Y decoder 6. The signal YD2 is composed of signals YD2(0) and YD2(1), which are respectively supplied to the even-numbered select transistor 31 and the odd-numbered select transistor 32. When the signal YD2(0) switches to the high level, the even-numbered main bit lines MBL(0), (2), (4) and (6) are selected. When the signal YD2(1) switches to the high level, the odd-numbered main bit lines MBL(1), (3), (5) and (7) are selected.

The combination of the signals YD1 and YD2 can select any one of the main bit lines MBL(0)-(7). For example, the main bit line MBL(0) can be selected by setting both the signals YD 1(0) and YD2(0) to the high level, and data read on the main bit line MBL(0) is applied to the read circuit 11. Similarly, the main bit line MBL(1) is selected by setting both the signals YD1(0) and YD2(1) to the high level, and the main bit line MBL(3) is selected by setting both the YD1(1) and YD2(1) to the high level.

Similarly, the write select transistor group 35 is composed of an even-numbered select transistor 36 arranged on the even-numbered main bit lines MBL(0), (2), (4) and (6), and an odd-numbered select transistor 37 arranged on the odd-numbered main bit lines MBL(1), (3), (5) and (7).

The write select transistor group 35 is supplied, via the gates of the transistors provided therein, with the signal YD2W obtained by decoding by the Y decoder 6. The signal YD2W is composed of signals YD2W(0) and YD2W(1), which are respectively supplied to the even-numbered select transistor 36 and the odd-numbered select transistor 37. When the signal YD2W(0) switches to the high level, the even-numbered main bit lines MBL(0), (2), (4) and (6) are selected. When the signal YD2W(1) switches to the high level, the odd-numbered main bit lines MBL(1), (3), (5) and (7) are selected.

In the programming of a memory cell MC, one of the main bit lines MBL(0)-(7) can be selected by the combination of the signals YD1 and YD2W. For example, the main bit line MBL(4) is selected when both the signals YD1(2) and YD2W(0) are set to the high level, and data from the write circuit 10 appears on the MBL(4).

The YRST transistors of the group 40 are respectively provided to the main bit lines MBL, as shown in FIG. 4, and receive, via the gates, the signal YRST generated by the Y decoder 6. The signal YRST is composed of signals YRST(0) and YRST(1).

The signal YRST(0) is applied to the YRST transistors respectively on the even-numbered main bit lines MBL(0), (2), (4) and (6), and the signal YRST(1) is applied to the YRST transistors on the odd-numbered main bit lines MBL(1), (3), (5) and (7). That is, the main bit lines MBL can be selected on the every other basis by the signal YRST(0) or YRST(1).

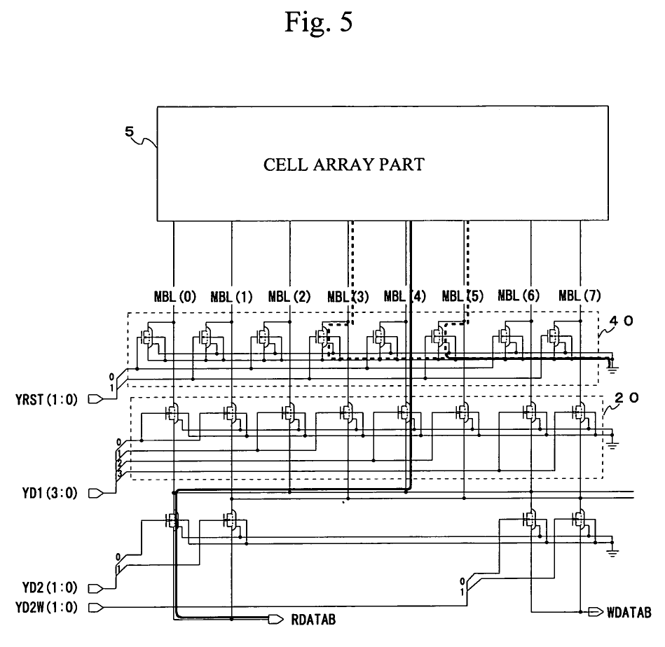

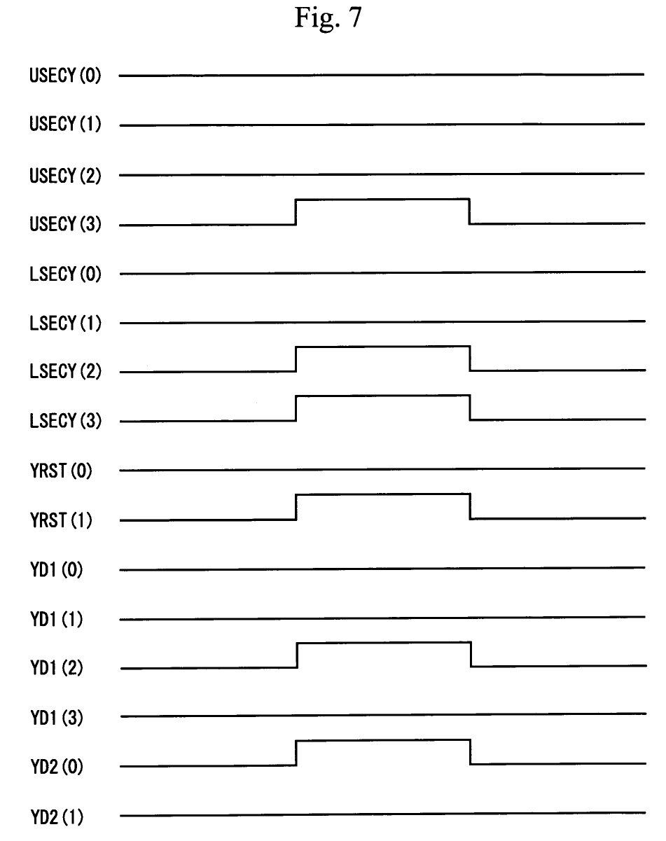

When the semiconductor device 1 selects one of the main bit lines MBL for reading, the selected main bit line MBL and the neighboring main bit lines MBL are set to a given voltage, which is the ground voltage Vss in the present embodiment. For example, when the signals YD 1(2) and YD2(0) are set to the high level, as shown in FIG. 7, the main bit line MBL(4) is selected for reading, as shown in FIG. 5. The Y decoder 6 sets the signals YD1(2) and YD2(0) to the high level, and sets the signal YRST(1) to the high level (see FIG. 7). The change of the signal YRST(1) to the high level connects all the odd-numbered main bit lines including the main bit lines MBL(3) and MBL(5) adjacent to the selected main bit line MBL(4) to the ground via a reset interconnection line (given interconnection line) 41 provided commonly in the sector. FIG. 5 shows a path that connects the main bit line MBL(4) to the read circuit 11, and another path that connects the neighboring main bit lines MBL(3) and (5) to the ground.

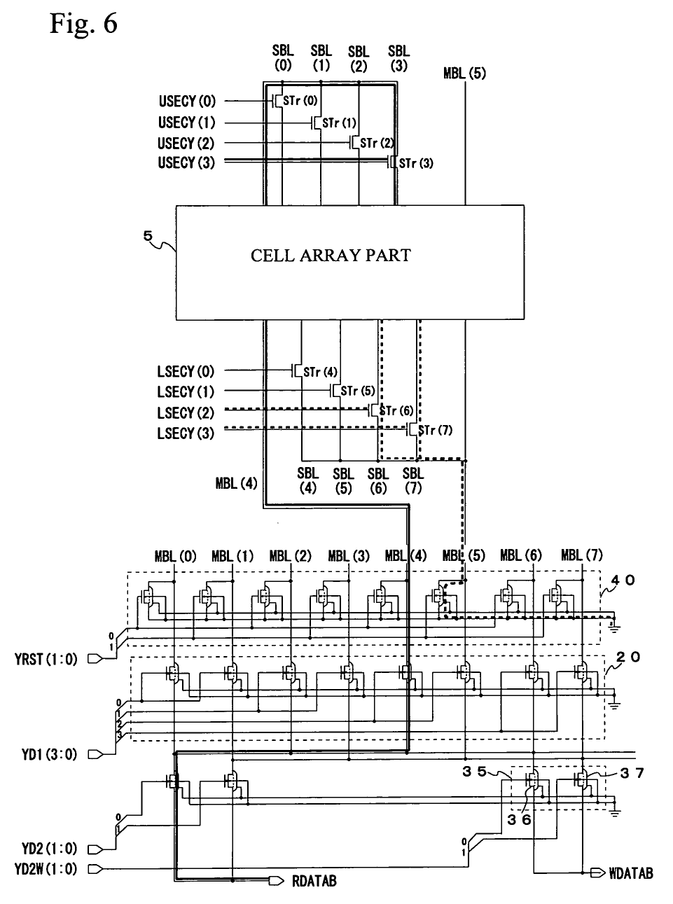

The selection of the sub bit lines SBL will now be described with reference to FIG. 6. For example, when the S decoder 7 selects the sub bit line SBL(3) connected to the main bit line MBL(4) by setting a signal USECY(3), a given voltage is applied to the sub bit line SBL(3), and is then applied to the drains of the memory cells MC connected thereto.

As shown in FIG. 7, the S decoder 7 changes the signal USECY(3) to the high level, and simultaneously changes LSECY(2) and LSECY(3) to the high level. The changes of LSECY(2) and LSECY(3) to the high level connect the sub bit lines SBL(6) and (7) adjacent to the selected sub bit line SBL(3). Since the main bit line MBL(5) is connected to the ground, the sub bit lines SBL(6) and (7) are also connected to the ground.

In this manner, the main bit lines MBL adjoining the selected main bit line MBL and the sub bit lines SBL adjoining the selected sub bit line SBL are connected to the ground so that the selected main and sub bit lines are shielded. It is thus possible to restrain noise from the adjoining the main and sub bit lines to the minimum and prevent degradation of the voltage margin. This makes it possible to prevent the occurrence of malfunction at the time of data reading. The main bit lines are set to the given voltage each time one of the main bit lines is selected. This arrangement contributes to preventing an increase of the number of components and a resultant increase of the circuit scale.

The preferred embodiments of the present invention have been described. The present invention is not limited to the specifically described embodiments, and various variations and modifications may be made without departing from the scope of the present invention.

What is claimed is:

1. A semiconductor device comprising:
a main bit line decoder for selecting one of main bit lines to which sub bit lines connected to memory cells are selectively connected; and
a first switch setting an adjacent main bit line adjacent to a selected one of the main bit lines at a given voltage under the control of the main bit line decoder.

2. The semiconductor device as claimed in claim 1, wherein the first switch connects the adjacent main bit line to an interconnection line that is set at the given voltage.

3. The semiconductor device as claimed in claim 1, wherein the first switch connects the adjacent main bit line to ground.

4. The semiconductor device as claimed in claim 1, further comprising:
a sub bit line decoder for selecting at least one of sub bit lines connected to said selected one of the main bit lines; and
a second switch connecting an adjacent sub bit line adjacent to said at least one of the sub bit lines to the adjacent main bit line under the control of the sub bit line decoder, so that the adjacent sub bit line can be set at the given voltage.

5. The semiconductor device as claimed in claim 1, wherein, at the time of reading, the main bit line decoder controls the first switch so that the adjacent main bit line can be set at the given voltage.

6. The semiconductor device as claimed in claim 1, wherein:
the first switch includes transistors each of which is provided on a corresponding one of the main bit lines; and
one of the transistors associated with the adjacent main bit line is turned on so that the adjacent main bit line can be set at the given voltage.

7. The semiconductor device as claimed in claim 4, wherein the second switch includes a transistor for connecting the adjacent sub bit line to the adjacent main bit line.

8. The semiconductor device as claimed in claim 1, wherein the semiconductor device has a NOR array in which:
the memory cells have charge hold layers and are arranged in an array having rows and columns;
word lines connect control gates of the memory cells in a direction of the rows; and
data is read from and written into the memory cells via the sub bit lines.

9. The semiconductor device as claimed in claim 8, wherein the array has an arrangement in which adjacent ones of the sub bit lines are connected to different main bit lines.

10. A method of reading data comprising the steps of:
selecting one of main bit lines to which sub bit lines connected to memory cells are selectively connected; and
setting an adjacent main bit line adjacent to a selected one of the main bit lines at a given voltage.
